(19) United States
(12) Patent Application Publication
(10) Pub. No.: US 2013/0241361 A1
(43) Pub. Date: Sep. 19, 2013

(54) MULTILAYER CERAMIC ELECTRONIC COMPONENT AND FABRICATION METHOD THEREOF

(71) Applicants: Chung Eun LEE, Suwon (KR); Doo Young Kim, Suwon (KR); Tae Hyeok Kim, Suwon (KR); Jae Yeol Choi, Suwon (KR)

(72) Inventors: Chung Eun LEE, Suwon (KR); Doo Young Kim, Suwon (KR); Tae Hyeok Kim, Suwon (KR); Jae Yeol Choi, Suwon (KR)

(73) Assignee: SAMSUNG ELECTRO-MECHANICS CO., LTD.

(21) Appl. No.: 13/480,147

(22) Filed: May 24, 2012

(30) Foreign Application Priority Data
Mar. 13, 2012 (KR) 10-2012-0025745

(51) Int. Cl. H01L 41/187; B32B 37/06; H01G 4/30; H01C 7/10; H01F 5/00

(52) U.S. Cl. 310/366; 338/22 R; 336/200; 361/301.4; 156/89.12

(57) ABSTRACT

There is provided a multilayer ceramic electronic component, including: a ceramic element including a plurality of dielectric layers laminated therein; a plurality of first and second internal electrodes formed on dielectric layers positioned in a middle portion of the ceramic element and alternately exposed from both ends of the ceramic element; a plurality of dummy electrodes formed on dielectric layers positioned in upper and lower portions of the ceramic element, respectively; and first and second external electrodes formed on both ends of the ceramic element and electrically connected to the exposed portions of the first and second internal electrodes, wherein the length of each of the dummy electrodes is longer than that of the first and second external electrodes covering the ceramic element.

### CROSS-REFERENCE TO RELATED APPLICATIONS

This application claims the priority of Korean Patent Application No. 10-2012-0025745 filed on Mar. 13, 2012, in the Korean Intellectual Property Office, the disclosure of which is incorporated herein by reference.

### BACKGROUND OF THE INVENTION

1. Field of the Invention

The present invention relates to a multilayer ceramic electronic component and a fabrication method thereof.

2. Description of the Related Art

Electronic components such as a capacitor, an inductor, a piezoelectric element, a varistor, a thermistor, and the like may include a ceramic material.

Among ceramic electronic components, a multilayer ceramic capacitor (MLCC) is an electronic component having strengths in that it is small, has a guaranteed high capacity, and is easily mounted.

Such an MLCC is a chip-type condenser mounted on a circuit board of various electronic products such as image display devices including a liquid crystal display (LCD), a plasma display panel (PDP), and the like, or a computer, a personal digital assistant (PDA), a mobile phone, and the like, in order to store or discharge electricity.

Recently, as image display devices have increased in both size and the speed of central processing units (CPUs) or the like, included therein, electronic devices generate increasing amounts of heat.

Thus, in order to ensure stability in integrated circuits (ICs) installed in electronic devices, MLCCs are required to have stable capacitance and reliability secured therein, even at high temperatures.

The MLCC includes external electrodes formed by coating a conductive material on both ends of a ceramic laminate.

In this case, the thickness of the external electrodes over corner portions of the ceramic laminate is less than the thickness of the external electrodes in a central portion thereof.

Thus, moisture, ions, conductive foreign objects, and the like, may infiltrate into an exposed surface of internal electrodes through the corner portions of the ceramic laminate to degrade insulation resistance and lower reliability of the multilayer ceramic electronic component.

In order to avoid such a defect, the internal electrodes of the MLCC are printed to have a structure having a margin portion along the circumference of dielectric layers, and here, a step is formed between the margin portion and the internal electrodes.

Thus, when a plurality of sheets with internal electrodes printed thereon are laminated and compressed with an identical pressure during a fabrication process, there is a limitation in compressing the margin portions having a step, causing some of the laminated dielectric layers to delaminate due to the step portions thereof.

Thus, the phenomenon in which the afore-mentioned moisture, ions, conductive foreign objects, and the like, infiltrate into the exposed surface of the internal electrodes may be aggravated, and such a defect may be exacerbated in an ultrahigh product having a high number of laminated sheets.

In Related Art Document 1, a dummy electrode is disposed between first and second internal electrodes and a structure in which a dummy electrode is formed on upper and lower portions of a ceramic element is not disclosed.

### [Related Art Document]

Korean Patent Laid-Open Publication No. 10-2011-0027321

### SUMMARY OF THE INVENTION

In the art, thus, a new scheme capable of suppressing delamination in a multilayer ceramic electronic component and allowing occurrence of delamination, if ever, on a side not affecting chip reliability, to thus significantly reduce infiltration of moisture, ions, conductive foreign objects, or the like, into a surface to which internal electrodes are exposed in a plating and driving environment.

According to an aspect of the present invention, there is provided a multilayer ceramic electronic component including: a ceramic element including a plurality of dielectric layers laminated therein; a plurality of first and second internal electrodes formed on dielectric layers positioned in a middle portion of the ceramic element among the plurality of dielectric layers and alternately exposed from both ends of the ceramic element; a plurality of dummy electrodes formed on dielectric layers positioned in upper and lower portions of the ceramic element, respectively; and first and second external electrodes formed on both ends of the ceramic element and electrically connected to the exposed portions of the first and second internal electrodes, wherein the length of each of the dummy electrodes is longer than that of the first and second external electrodes covering the ceramic element.

The dummy electrodes may be formed to be spaced apart from each other on a single dielectric layer, and may include first and second dummy electrodes connected to the first and second external electrodes, respectively.

The length of each of the first and second dummy electrodes may be less than half of the length of the ceramic element.

The first and second dummy electrodes may be formed to have the same length.

The first and second dummy electrodes may be formed to have different lengths.

The space between the first and second dummy electrodes may range from about 0.5% to 1.5% of the length of the ceramic element.

The dummy electrodes may include: a first dummy electrode connected to one of the first and second external electrodes; and a second dummy electrode connected to the other of the first and second external electrodes, different from that to which the first dummy electrode is connected, wherein the first and second dummy electrodes are formed such that the dummy electrodes exposed in the same direction as that of the internal electrodes formed on the outermost surfaces of the ceramic element are formed in upper and lower portions of the ceramic element, respectively.

The ceramic element may further include: dielectric cover layers formed on upper and lower portions of the ceramic element.

The dummy electrode may be formed such that a corner portion of a portion thereof exposed from the end of the ceramic element is sloped.

The dummy electrode may be formed such that a corner portion of a portion thereof positioned at an inner side of the ceramic element is sloped.

According to another aspect of the present invention, there is provided a method of fabricating a multilayer ceramic electronic component, including: forming a first internal electrode pattern on each of a plurality of first ceramic sheets such that the first internal electrode pattern is exposed from one end of each of the first ceramic sheets; forming a second internal electrode pattern on each of a plurality of second ceramic sheets such that the second internal electrode pattern is exposed from the other end of each of the second ceramic sheets; forming a plurality of dummy electrode patterns on a plurality of third ceramic sheets; laminating the plurality of the third ceramic sheets, alternately laminating a plurality of first and second ceramic sheets thereon, and laminating the plurality of third ceramic sheets again thereon to form a laminate; firing the laminate; and forming first and second external electrodes on both ends of the laminate such that the first and second external electrodes cover exposed portions of the first and second internal electrode patterns, wherein the length of each of the dummy electrodes is longer than that of the first and second external electrodes covering the laminate.

In the forming of the dummy electrode patterns, first and second dummy electrode patterns may be formed on the single third ceramic sheet such that they are spaced apart from each other and exposed from both ends, respectively.

In the forming of the dummy electrode patterns, the length of each of the first and second dummy electrode patterns maybe shorter than half of the length of the third ceramic sheet.

In the forming of the dummy electrode patterns, the first and second dummy electrode patterns may be formed to have the same length so as to be symmetrical with regard to each other based on the center of the third ceramic sheet.

In the forming of the dummy electrode patterns, the first and second dummy electrode patterns may be formed to have different lengths on the third ceramic sheet.

In the forming of the dummy electrode patterns, the space between the first and second dummy electrode patterns may range from about 0.5% to 1.5% of the length of the third ceramic sheet.

The dummy electrode patterns may include: a first dummy electrode pattern connected to one of the first and second external electrodes; and a second dummy electrode pattern connected to the other of the first and second external electrode patterns, different from the one to which the first dummy electrode pattern is connected, wherein the first and second dummy electrode patterns are formed such that the dummy electrode patterns are exposed in the same directions as those of the internal electrodes formed on the outermost surfaces are formed in upper and lower portions of the ceramic element, respectively.

The method may further include: forming dielectric cover layers on upper and lower portions of the laminate, before the firing of the laminate.

In the forming of the dummy electrode patterns, the dummy electrode pattern may be formed such that a corner portion of a portion thereof exposed from the end of the third ceramic sheet is sloped.

In the forming of the dummy electrode patterns, the dummy electrode patterns may be formed such that a corner portion of a portion thereof positioned at an inner side of the third ceramic sheet is sloped.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view showing a schematic structure of a multilayer ceramic capacitor (MLCC) according to an embodiment of the present invention;

FIG. 2 is a cross-sectional view taken along line A-A′ in FIG. 1;

FIG. 3 is an exploded perspective view showing a dielectric layer, a first internal electrode, a second internal electrode, a dummy electrode, and upper and lower cover layers of the MLCC of FIG. 2;

FIG. 4 is a perspective view showing a coupled structure of FIG. 3;

FIG. 5 is a perspective view showing a dielectric layer with the first dummy electrode of FIG. 3 formed thereon;

FIG. 6 is a micrograph of a corner portion of FIG. 4;

FIG. 7 is an exploded perspective view showing a dielectric layer, a first internal electrode, a second internal electrode, a dummy electrode, and upper and lower cover layers of an MLCC according to another embodiment of the present invention;

FIG. 8 is a perspective view showing a coupled structure of FIG. 7;

FIG. 9 is a perspective view showing a dielectric layer with the first dummy electrode of FIG. 7 formed thereon;

FIG. 10 is a perspective view showing a dummy electrode according to another embodiment of the present invention; and

FIG. 11 is a perspective view showing a dummy electrode according to another embodiment of the present invention.

### DETAILED DESCRIPTION OF THE EMBODIMENTS

Embodiments of the present invention will now be described in detail with reference to the accompanying drawings.

The embodiments of the present invention may be modified in many different forms and the scope of the invention should not be limited to the embodiments set forth herein.

Rather, these embodiments are provided so that this disclosure will be thorough and complete, and will fully convey the concept of the invention to those skilled in the art.

In the drawings, the shapes and dimensions of elements maybe exaggerated for clarity, and the same reference numerals will be used throughout to designate the same or like components.

In addition, like reference numerals denote parts performing similar functions and actions throughout the drawings.

In addition, unless explicitly described to the contrary, “comprising” any components will be understood to imply the inclusion of other components but not the exclusion of any other components.

The present invention relates to a ceramic electronic component, and ceramic electronic components according to an embodiment of the present invention may include a multilayer ceramic capacitor (MLCC), an inductor, a piezoelectric element, a varistor, a chip resistor, a thermistor, and the like, and hereinafter, a multilayer ceramic capacitor (MLCC) will be described as an example of a ceramic electronic product.

Also, in the present embodiment, for the sake of explanation, the surfaces of a ceramic element on which external electrodes are formed will be determined as both of left and right ends and surfaces perpendicular to the foregoing surfaces will be determined as left and right lateral sides.

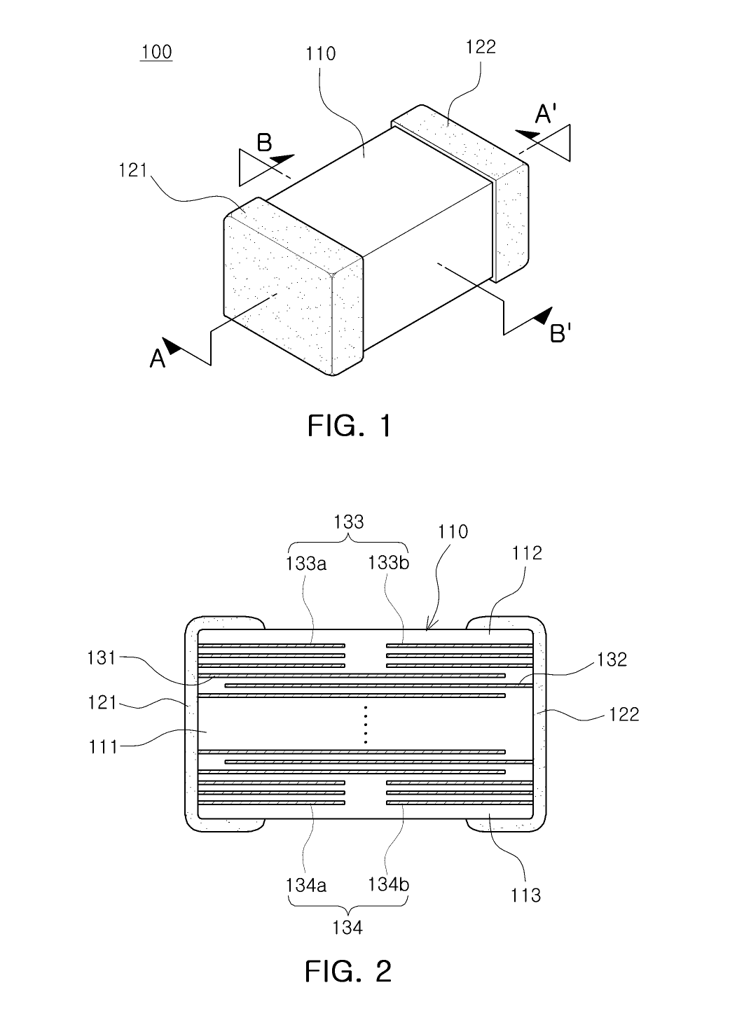

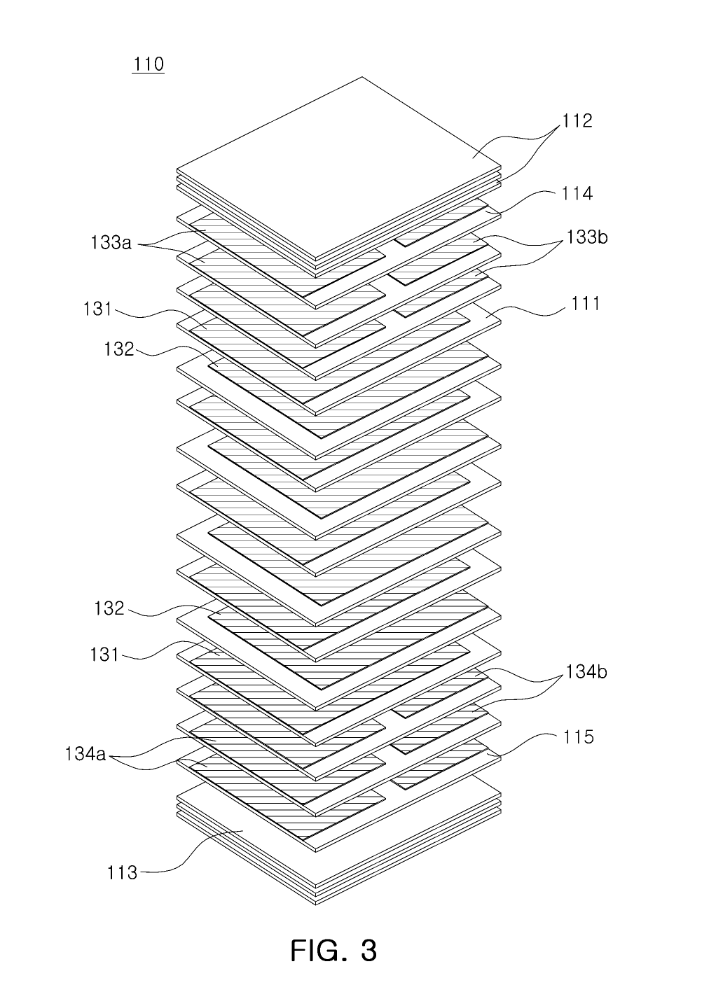

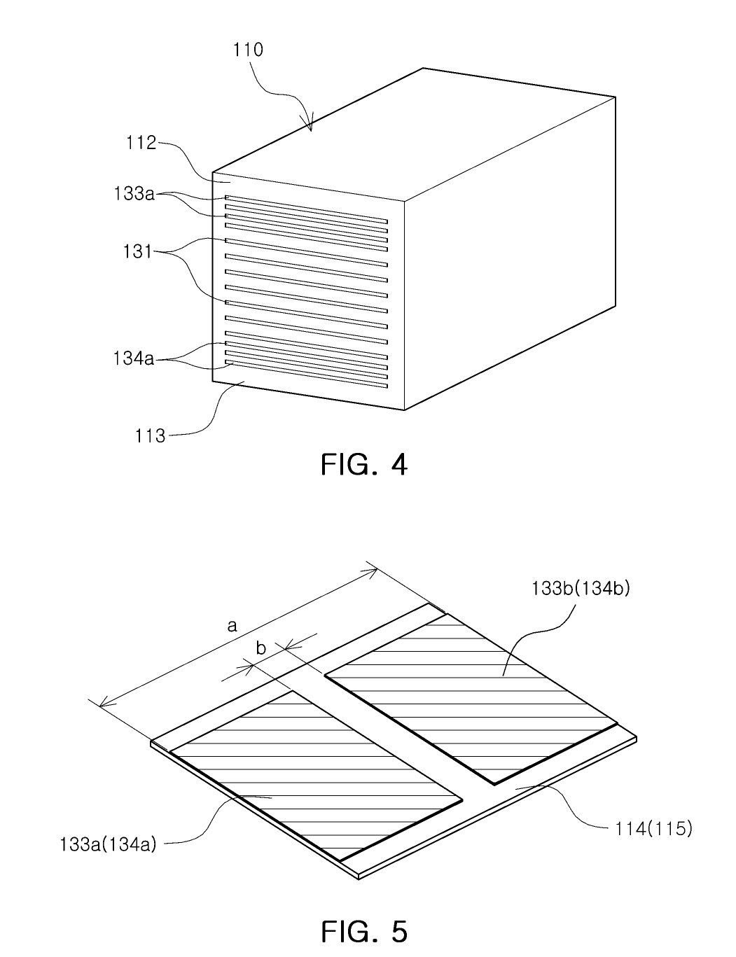

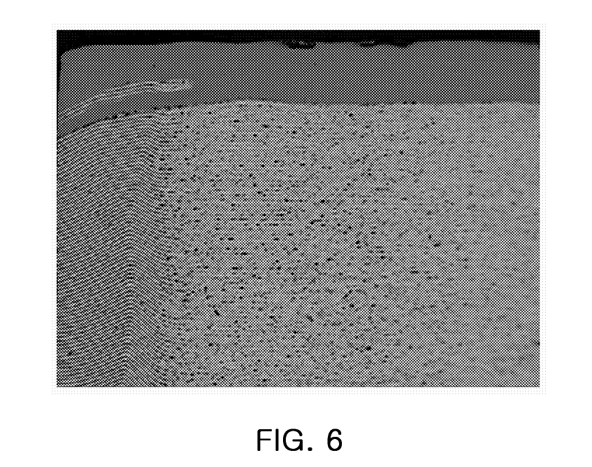

With reference to FIGS. 1 through 5, an MLCC 100 according to the present embodiment may include a ceramic element 110 in which a plurality of dielectric layers are laminated, a plurality of first and second internal electrodes 131 and 132 formed on a dielectric layer 111 positioned in a middle portion of the ceramic element 110 and alternately exposed from both ends of the ceramic element 110, and a plurality of dummy electrodes 133 and 134 formed on dielectric layers 114 and 115 positioned in upper and lower portions of the ceramic element 110.

Also, first and second external electrodes 121 and 122 are formed on both ends of the ceramic element 110 and electrically connected to the exposed portions of the first and second internal electrodes 131 and 132.

Here, the dummy electrodes 133 and 134 may be formed to be longer than the lengths of the portions of the first and second external electrodes 121 and 122 that cover the sides of the ceramic element 110.

In the present embodiment, the dummy electrodes 133 and 134 are formed to be separated from each other on the single dielectric layer 111, and may include first dummy electrodes 133a and 134a and second dummy electrodes 133b and 134b alternately exposed from one of both ends of the ceramic element 110.

The dummy electrodes 133 and 134 may serve to reduce a step of the ceramic element 110 to suppress an occurrence of delamination or allow delamination to occur at the dummy electrodes 133 and 134 themselves, rather than among the first and second internal electrodes 131 and 132, if ever, thus improving product reliability.

Here, in order to significantly reduce step generation with the first and second internal electrodes 131 and 132, specifically, the dummy electrodes 133 and 134 may be formed to be as large as possible, and here, the dummy electrodes 133 and 134 maybe formed to have a width of 50% or more with respect to the width of the dielectric layers 114 and 115.

Also, the first dummy electrodes 133a and 134a and the second dummy electrodes 133b and 134b may have a length less than half of the length (a) of the ceramic element 110.

Thus, in the present embodiment, a space (b) set to range from about 0.5% to 1.5% of the overall length (a) of the ceramic element 110 is formed between the first dummy electrodes 133a and 134a and the second dummy electrodes 133b and 134b, and the space (b) maybe utilized for the purpose of preventing printing paste from spreading, or the like, in forming the electrodes.

Also, in the present embodiment, the first dummy electrodes 133a and 134a and the second dummy electrodes 133b and 134b are formed to have the same length, forming a horizontally symmetrical structure, but the present invention is not limited thereto.

Namely, regarding the dummy electrodes 133 and 134, the first dummy electrodes 133a and 134a and the second dummy electrodes 133b and 134b may be variably modified such that they have different lengths to form an asymmetrical structure.

Also, when an excessively large number of dummy electrodes 133 and 134 were laminated in the upper and lower portions of the ceramic element 110, the size of the chip would be excessively increased.

Thus, the dielectric layers 114 and 115 having the dummy electrodes 133 and 134 may be formed within a range in which step generation is restrained. For example, the dielectric layers 114 and 115 may be formed to have a thickness ranging from about 10% to 20% of that of the dielectric layer 111 in which the first and second internal electrodes 131 and 132 are formed, but the present invention is not limited thereto.

Also, the amounts of the laminated dielectric layers 114 and 115 having the dummy electrodes 133 and 134 formed thereon, respectively, may be identical, but the present invention is not limited thereto, and when necessary, the amounts of laminated dielectric layers 114 and 115 having the dummy electrodes 133 and 134 may be different.

Also, dielectric cover layers 112 and 113 maybe formed on the outermost surfaces, namely, on upper and lower surfaces as depicted in FIG. 1, of the ceramic element 110.

Here, when necessary, two or more dielectric cover layers 112 may be laminated in a vertical direction so as to be formed.

The ceramic element 110 may be formed by laminating a plurality of dielectric layers 111.

Here, the plurality of dielectric layers 111 constituting the ceramic element 110 in a sintered state may be integrated with adjacent dielectric layers 111 such that a boundary therebetween cannot be recognized.

Also, the ceramic element 110 may generally have a rectangular parallelepiped shape, but a shape thereof is not limited thereto.

Also, dimensions of the ceramic element 110 are not particularly limited, but for example, the ceramic element 110 may be configured to have a size of 0.6 mm×0.3 mm such that the MLCC 100 has a high capacity of 1.0 μF or more.

The dielectric layers 111, 114, and 115 constituting the ceramic element 110 may include ceramic powder, e.g., BaTiO₃-based ceramic powder, or the like.

The BaTiO₃-based ceramic powder may include (Ba₁₋ₓCaₓ)TiO₃, Ba(Ti_{1-y}Ca_{y})O₃, (Ba₁₋ₓCaₓ) (Ti_{1-y}Zr_{y})O₃, Ba(Ti_{1-y}Zr_{y})O₃, or the like, obtained by employing a portion of Ca, Zr, or the like, in BaTiO₃, but the present invention is not limited thereto.

An average particle diameter of ceramic powder may be 0.8 μm or less, and specifically, may range from about 0.05 μm to 0.5 μm, but the present invention is not limited thereto.

The dielectric layer 111 may further include transition metal oxide or carbide, a rare earth element, or at least one of Mg and Al, along with ceramic powder, as necessary.

Also, the thickness of the dielectric layer 111 may be arbitrarily changed according to a capacity design of the MLCC 100.

In the present embodiment, the thickness of each of the dielectric layer 111 may be 1.0 μm or less, and specifically, range from about 0.01 μm to 1.0 μM, but the present invention is not limited thereto.

The first and second internal electrodes 131 and 132 and the dummy electrodes 133 and 134 may be formed of conductive paste including conductive metal.

Here, the conductive metal may be Ni, Cu, Pd, or an alloy thereof, but the present invention is not limited thereto.

As for the first and second internal electrodes 131 and 132 and the dummy electrodes 133 and 134, an internal electrode pattern is formed on each of ceramic green sheets forming the dielectric layers 111, 114, and 115 with conductive paste, through a printing method such as a screen printing method or a gravure printing method, and the ceramic green sheets with the internal electrode pattern printed thereon may be alternately laminated and fired to form the ceramic element 110.

Here, capacitance is formed in a region in which the first and second internal electrodes 131 and 132 overlap each other.

Also, the thickness of the first and second internal electrodes 131 and 132 may be determined according to an intended purpose. For example, the thickness of the first and second internal electrodes 131 and 132 may range from about 0.2 μm to 1.0 μm in consideration of the size of the ceramic element 110, but the present invention is not limited thereto.

An operation of the MLCC 100 according to the present embodiment configured as described above will be described.

The dielectric layer 111 has a margin portion between the dielectric layer 111 and the first and second internal electrodes 131 and 132.

Such a margin portion serves to prevent a foreign object from infiltrating into the first and second internal electrodes 131 and 132 after the ceramic element 110 is formed by laminating the respective dielectric layers 111, and also serves to protect the first and second internal electrodes 131 and 132 against impact to thus prevent an electric short circuit.

Here, due to a step between the first and second internal electrodes 131 and 132 and the margin portion, when the printed sheets are laminated and compressed, delamination may occur at a corner portion of the ceramic element 110, so moisture, ions, or a conductive foreign object may infiltrate into exposed portions of the first and second internal electrodes 131 and 132 to degrade insulation resistance and lower reliability, or the like.

Here, when the first and second internal electrodes 131 and 132 are formed on all of the dielectric layers 111, the width of the margin portion would be increased to improve such a defect.

In this case, however, influence of the step on the corner portion of the ceramic element 110 may be increased and a movement of a material to the step portion may be insufficient in the compressing process, degrading density of the margin portion to potentially cause cracks.

Also, as the internal electrodes may be increased to fill up the empty step portion, disconnection of the internal electrodes may be aggravated to potentially lower reliability.

However, in the MLCC 100 according to the present embodiment, the electrodes formed on the dielectric layers 114 and 115 positioned in upper and lower portions of the ceramic element 110 may be formed as the dummy electrodes 133 and 134 to allow the corner portion of the ceramic element 110 to have a margin portion, whereby the first and second internal electrodes 131 and 132, serving to play a role of an actual electrical connection, are formed in positions spaced apart from the corner portion acting as a main infiltration path of a foreign object, and although delamination occurs, it is induced to occur at the dummy electrodes 133 and 134 to thereby prevent a foreign object from infiltrating into the first and second internal electrodes 131 and 132, thus improving product reliability.

Thus, in the ultra-high capacity type multilayer ceramic electronic component having the foregoing structure, connectivity of the electrodes may be maintained and the probability of infiltration of a conductive foreign object into the corner portion on which external electrodes are coated to be thin in an ultra-high capacity type multilayer ceramic electronic component with a relatively small margin and thin cover thereof can be lowered, thus improving reliability.

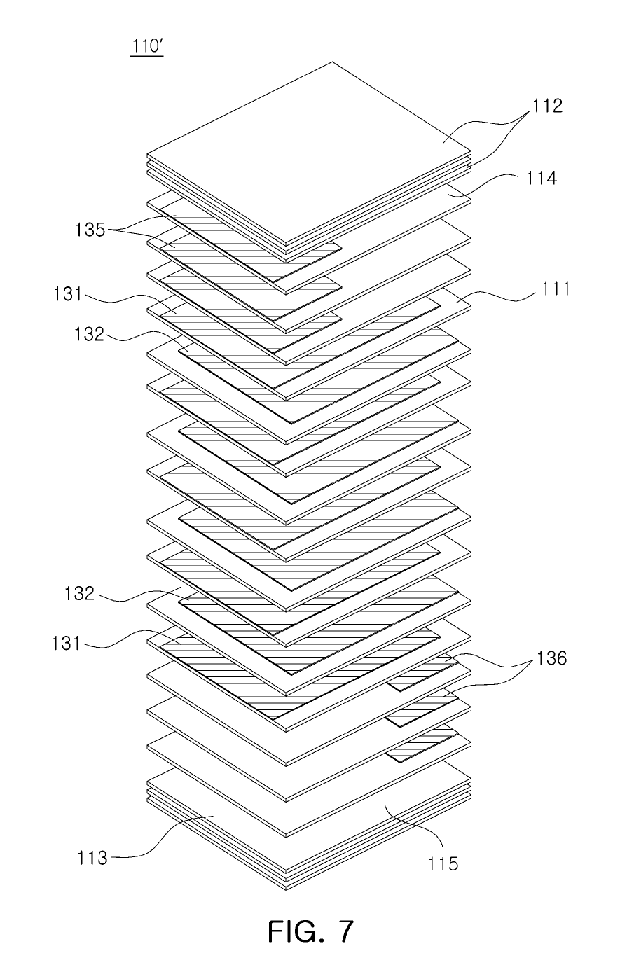

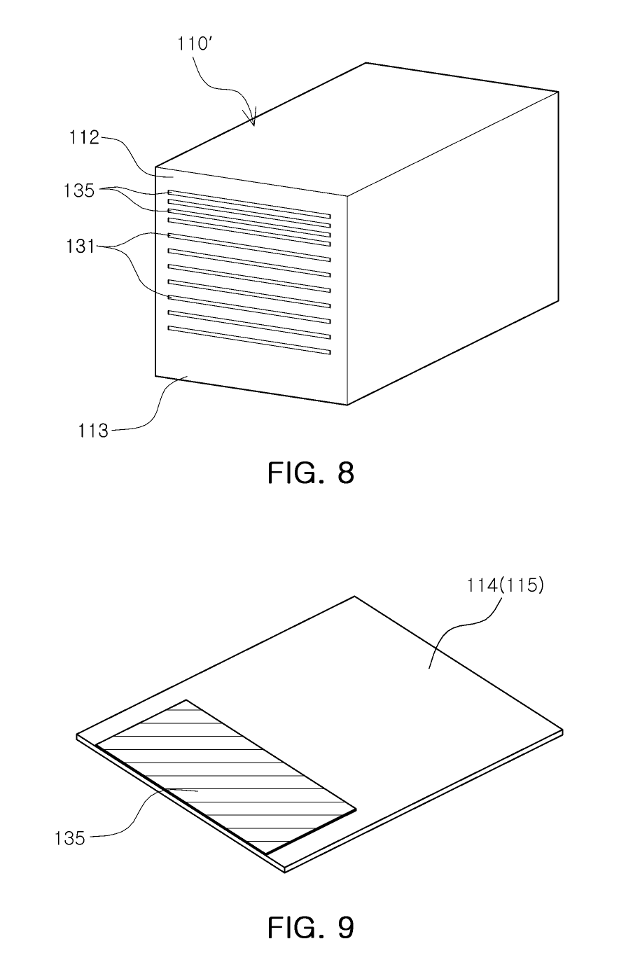

FIGS. 7 through 11 show an MLCC according to another embodiment of the present invention.

Here, the structure in which first and second external electrodes are formed on both ends of a ceramic element 110′ is the same as that of the one embodiment of the present invention as described above, so a detailed description thereof will be omitted to avoid repetition, and only components constituting the ceramic element 110′ will be illustrated and described in detail as follows.

With reference to FIGS. 7 through 9, the ceramic element 110′ is formed by laminating a plurality of dielectric layers 111, 114, and 115 in a vertical direction.

The first and second internal electrodes 131 and 132 maybe formed on the dielectric layers 111 positioned in a middle portion of the ceramic element 110′ such that they are alternately exposed from both ends of the ceramic element 110′, and the first and second dummy electrodes 135 and 136 may be formed on the dielectric layers 114 and 115 positioned in upper and lower portions of the ceramic element 110′, respectively.

Here, the first and second dummy electrodes 135 and 136 may be formed to be exposed only from the same end as that from which the internal electrodes formed on the outermost surface are exposed in a vertical direction of the ceramic element 110′.

For example, in the present embodiment, the first dummy electrode 135 formed on the upper dielectric layer 114 of the ceramic element 110′ is formed to be exposed from a left end from which the first internal electrode 131 formed on the uppermost surface of the ceramic element 110′ is exposed, and the second dummy electrode 136 formed on the lower dielectric layer 115 of the ceramic element 110′ is exposed only from a right end from which the second internal electrode 132 formed on the lowermost surface of the ceramic element 110′ is exposed.

Thus, when a laminate is formed by compressing the plurality of laminated dielectric layers 111, 114, and 115, an occurrence of a delamination due to a step between the internal electrodes and a margin portion at both ends of the upper and lower portions of the ceramic element 110′ may be restrained or, if ever, delamination may be induced to occur only at the first and second dummy electrodes 135 and 136 formed to be exposed toward the same end of the dielectric layer as that of the first and second internal electrodes 131 and 132, whereby moisture, ions, a conductive foreign object may be prevented from infiltrating into the first and second internal electrodes 131 and 132, thus preventing degradation of reliability.

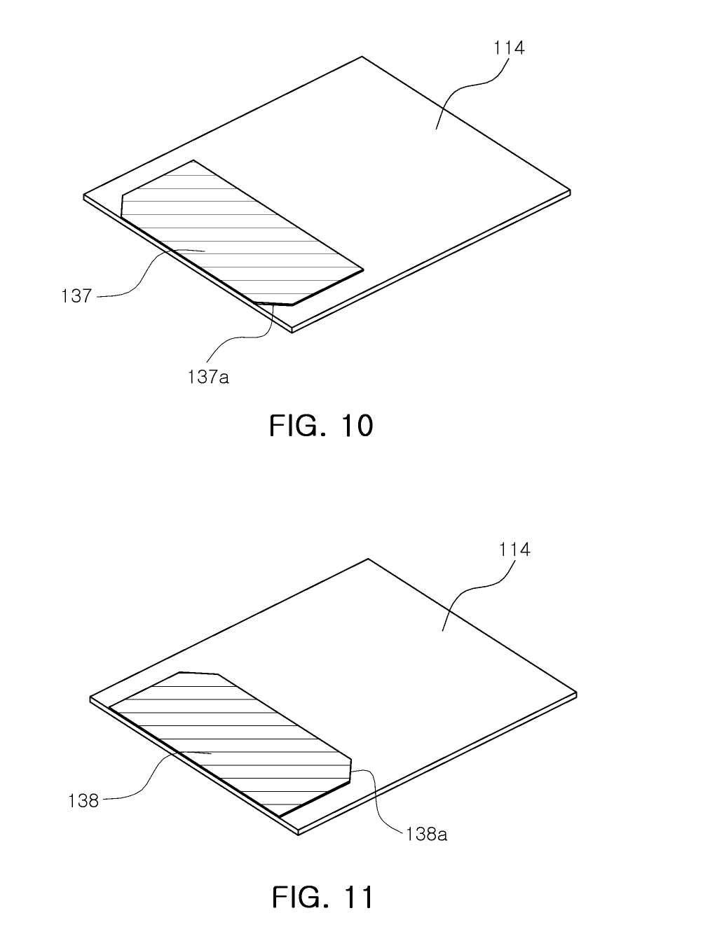

FIGS. 10 and 11 are views showing various forms of the first and second dummy electrodes according to another embodiment of the present invention.

The first and second dummy electrodes have a symmetrical shape based on the center of the ceramic element. Hereinafter, in order to avoid repeated description of the second dummy electrode, only the first dummy electrode will be described.

With reference to FIG. 10, a first dummy electrode 137 may be formed such that a portion exposed from one end of the dielectric layer 114 has a width smaller than that of a portion positioned at an inner side of the dielectric layer 114, and to this end, a left corner portion 137a of the first dummy electrode 137 may be tapered to have a width narrowed toward one end of the dielectric layer 114.

With reference to FIG. 11, a first dummy electrode 138 may be formed such that a corner portion of a portion thereof positioned at an inner side of the dielectric layer 114 is sloped, and to this end, a right corner portion 138a of the first dummy electrode 138 may tapered to have a width narrowed toward the inner side of the dielectric layer 114.

Hereinafter, a method of fabricating the MLCC 100 according to an embodiment of the present invention will be described.

First, a plurality of ceramic green sheets are prepared.

The ceramic green sheets are prepared to form the dielectric layers 111, 114, and 115 of the ceramic element 110. Slurry may be fabricated by mixing a ceramic powder, a polymer and a solvent, and then, processed into a form of sheets having a thickness of a few μm through a technique such as a doctor blade technique, or the like, thus forming the ceramic green sheets.

Next, conductive paste is printed to have a certain thickness, for example, ranging from 0.2 μm to 1.0 μm on at least one surface of each of the ceramic green sheets to form a first internal electrode pattern, a second internal electrode pattern, and dummy electrode patterns.

The first and second internal electrode patterns may be formed by printing conductive paste such that a margin portion is formed along the edge portion of each of the ceramic green sheets.

Here, the first internal electrode pattern is formed on a first ceramic sheet such that it is exposed from one end of the first ceramic sheet, and the second internal electrode pattern is formed on a second ceramic sheet in the opposite direction to that of the first internal electrode pattern such that it is exposed from the other end of the second ceramic sheet.

The dummy electrode patterns may be formed such that first and second dummy electrode patterns exposed from both ends, respectively, are spaced apart from each other on a third ceramic sheet.

Here, the first and second dummy electrode patterns may be formed to have a length less than half of the length of the third ceramic sheet, and specifically, the space between the first and second dummy electrode patterns may range from 0.5% to 1.5% of the length of the third ceramic sheet, but the present invention is not limited thereto.

Also, the first and second dummy electrode patterns may be formed to have the same length so as to be symmetrical with regard to each other, based on the center of the third ceramic sheet, but the present invention is not limited thereto and, when necessary, the first and second dummy electrode patterns may have different lengths.

As the method of printing conductive paste, a screen printing method, a gravure printing method, or the like, may be used, and the conductive paste may include metal powder, ceramic powder, silica (SiO₂) powder, or the like.

Also, an average particle diameter of the conductive paste may range from about 50 nm to 400 nm, but the present invention is not limited thereto.

Also, the metal power maybe at least one of nickel (Ni), manganese (Mn), chromium (Cr), cobalt (Co), and aluminum (Al), or an alloy thereof may be used.

And then, a plurality of the third ceramic sheets are laminated, a plurality of the first and second ceramic sheets are alternately laminated thereon, a plurality of the third ceramic sheets are laminated thereon, and then, the resultant structure is compressed in the lamination direction to compress the plurality of first to third laminated ceramic sheets and the first and second internal electrode patterns formed on the plurality of first to third ceramic green sheets and the dummy electrode patterns in a vertical direction to form a laminate.

Here, at least one or more dielectric cover layers 112 and 113 may be further laminated on upper and lower surfaces of the laminate.

The dielectric cover layers 112 and 113 may be formed of ceramic sheets having the same composition as that of the first to third ceramic sheets, and are different from the first to third ceramic sheets in that the dielectric cover layers 112 and 113 do not include an electrode pattern.

Thereafter, the laminate is cut in every region corresponding to each MLCC to form chips, and the chips are fired at a high temperature, thus completing the ceramic element 110.

Then, the first and second external electrodes 121 and 122 are formed on both ends of the ceramic element 110 such that the first and second external electrodes 121 and 122 cover exposed portions of the first and second internal electrode patterns so as to be electrically connected thereto, respectively.

Here, surfaces of the first and second external electrodes 121 and 122 may be plated with nickel, tin, or the like, as necessary.

Meanwhile, in a different embodiment of the dummy electrode patterns, in forming the laminate by compressing the ceramic sheets, only one type of the first and second dummy electrode patterns may be formed on upper and lower portions of the laminate such that it is exposed in the same direction as that of the internal electrode patterns formed on the outermost surfaces of the laminate.

As set forth above, according to embodiments of the invention, since a step may be improved by forming dummy electrodes at upper and lower portions of the ceramic element, an occurrence of a delamination may be restrained, and if ever, delamination may be induced to occur at the dummy electrodes, thus significantly reducing an infiltration of moisture, ions, a conductive foreign object, or the like, into the exposed surface of the inner electrodes through a corner portion of the ceramic element in a plating and driving environment and preventing a degradation of insulation resistance and a degradation in the reliability of the multilayer ceramic electronic component.

While the present invention has been shown and described in connection with the embodiments, it will be apparent to those skilled in the art that modifications and variations can be made without departing from the spirit and scope of the invention as defined by the appended claims.

What is claimed is:

1. A multilayer ceramic electronic component comprising:
a ceramic element including a plurality of dielectric layers laminated therein;
a plurality of first and second internal electrodes formed on dielectric layers positioned in a middle portion of the ceramic element among the plurality of dielectric layers and alternately exposed from both ends of the ceramic element;
a plurality of dummy electrodes formed on dielectric layers positioned in upper and lower portions of the ceramic element, respectively; and
first and second external electrodes formed on both ends of the ceramic element and electrically connected to the exposed portions of the first and second internal electrodes,
the length of each of the dummy electrodes being longer than that of the first and second external electrodes covering the ceramic element.

2. The multilayer ceramic electronic component of claim 1, wherein the dummy electrodes are formed to be spaced apart from each other on a single dielectric layer, and include first and second dummy electrodes connected to the first and second external electrodes, respectively.

3. The multilayer ceramic electronic component of claim 2, wherein the length of each of the first and second dummy electrodes is less than half of the length of the ceramic element.

4. The multilayer ceramic electronic component of claim 2, wherein the first and second dummy electrodes are formed to have the same length.

5. The multilayer ceramic electronic component of claim 2, wherein the first and second dummy electrodes are formed to have different lengths.

6. The multilayer ceramic electronic component of claim 2, wherein the space between the first and second dummy electrodes ranges from about 0.5% to 1.5% of the length of the ceramic element.

7. The multilayer ceramic electronic component of claim 1, wherein the dummy electrodes include:
a first dummy electrode connected to one of the first and second external electrodes; and
a second dummy electrode connected to the other of the first and second external electrodes, different from that to which the first dummy electrode is connected,
wherein the first and second dummy electrodes are formed such that the dummy electrodes exposed in the same direction as that of the internal electrodes formed on the outermost surfaces of the ceramic element are formed in upper and lower portions of the ceramic element, respectively.

8. The multilayer ceramic electronic component of claim 1, further comprising dielectric cover layers formed on upper and lower portions of the ceramic element.

9. The multilayer ceramic electronic component of claim 1, wherein the dummy electrode is formed such that a corner portion of a portion thereof exposed from the end of the ceramic element is sloped.

10. The multilayer ceramic electronic component of claim 1, wherein the dummy electrode is formed such that a corner portion of a portion thereof positioned at an inner side of the ceramic element is sloped.

11. A method of fabricating a multilayer ceramic electronic component, the method comprising:
forming a first internal electrode pattern on each of a plurality of first ceramic sheets such that the first internal electrode pattern is exposed from one end of each of the first ceramic sheets;
forming a second internal electrode pattern on each of a plurality of second ceramic sheets such that the second internal electrode pattern is exposed from the other end of each of the second ceramic sheets;
forming a plurality of dummy electrode patterns on a plurality of third ceramic sheets;
laminating the plurality of the third ceramic sheets, alternately laminating a plurality of first and second ceramic sheets thereon, and laminating the plurality of third ceramic sheets again thereon to form a laminate;
firing the laminate; and
forming first and second external electrodes on both ends of the laminate such that the first and second external electrodes cover exposed portions of the first and second internal electrode patterns,
the length of each of the dummy electrodes being longer than that of the first and second external electrodes covering the laminate.

12. The method of claim 11, wherein, in the forming of the dummy electrode patterns, first and second dummy electrode patterns are formed on the single third ceramic sheet such that they are spaced apart from each other and exposed from both ends, respectively.

13. The method of claim 12, wherein, in the forming of the dummy electrode patterns, the length of each of the first and second dummy electrode patterns is shorter than half of the length of the third ceramic sheet.

14. The method of claim 12, wherein, in the forming of the dummy electrode patterns, the first and second dummy electrode patterns are formed to have the same length so as to be symmetrical with regard to each other based on the center of the third ceramic sheet.

15. The method of claim 12, wherein, in the forming of the dummy electrode patterns, the first and second dummy electrode patterns are formed to have different lengths on the third ceramic sheet.

16. The method of claim 12, wherein, in the forming of the dummy electrode patterns, the space between the first and second dummy electrode patterns ranges from about 0.5% to 1.5% of the length of the third ceramic sheet.

17. The method of claim 11, wherein the dummy electrode patterns include:
a first dummy electrode pattern connected to one of the first and second external electrodes; and
a second dummy electrode pattern connected to the other of the first and second external electrode patterns, different from the one to which the first dummy electrode pattern is connected,
wherein the first and second dummy electrode patterns are formed such that the dummy electrode patterns are exposed in the same directions as those of the internal electrodes formed on the outermost surfaces are formed in upper and lower portions of the ceramic element, respectively.

18. The method of claim 11, further comprising forming dielectric cover layers on upper and lower portions of the laminate, before the firing of the laminate.

19. The method of claim 11, wherein, in the forming of the dummy electrode patterns, the dummy electrode pattern is formed such that a corner portion of a portion thereof exposed from the end of the third ceramic sheet is sloped.

20. The method of claim 11, wherein, in the forming of the dummy electrode patterns, the dummy electrode pattern is formed such that a corner portion of a portion thereof positioned at an inner side of the third ceramic sheet is sloped.
